(19) United States
(12) Patent Application Publication
(10) Pub. No.: US 2025/0035724 A1
(43) Pub. Date: Jan. 30, 2025

(54) MAGNET ARRANGEMENT COMPRISING A HIGH TEMPERATURE SUPERCONDUCTOR FOR UTILIZATION IN A MAGNETIC RESONANCE IMAGING SYSTEM

(71) Applicant: Siemens Healthineers AG, Forchheim (DE)

(72) Inventors: Matthias GEBHARDT, Erlangen (DE); Michael MALLETT, Faringdon (GB)

(73) Assignee: Siemens Healthineers AG, Forchheim (DE)

(21) Appl. No.: 18/915,735

(22) Filed: Oct. 15, 2024

Related U.S. Application Data
(62) Division of application No. 17/405,123, filed on Aug. 18, 2021.

(30) Foreign Application Priority Data
Aug. 25, 2020 (DE) 10 2020 210 739.4

(51) Int. Cl. G01R 33/3815; G01R 33/38

(52) U.S. Cl. CPC G01R 33/3815; G01R 33/3802; G01R 33/3804

(57) ABSTRACT

A magnet arrangement is for use in a magnetic resonance imaging system including at least one magnet including a high temperature superconductor to provide a magnetic field in an imaging volume for acquiring magnetic resonance imaging data. A magnetic resonance imaging system includes a magnet arrangement with at least one magnet, including a high temperature superconductor, to confine an imaging volume in at least one spatial direction. The magnetic resonance imaging system is configured to acquire magnetic resonance imaging data from at least a body region of a patient positioned in the imaging volume. Further a method is for manufacturing a magnet arrangement via an additive manufacturing device, including aligning a first magnet segment with a second magnet segment and bringing the first magnet segment into contact with the second magnet segment; and performing a joining process to bond the first magnet segment to the second magnet segment.

### PRIORITY STATEMENT

The present application is a divisional of U.S. patent application Ser. No. 17/405,123, filed Aug. 18, 2021, which claims priority under 35 U.S.C. § 119 to German patent application number DE 102020210739.4 filed Aug. 25, 2020, the entire contents of each of which are incorporated herein by reference.

### FIELD

Example embodiments of the invention generally relate to a magnet arrangement for use in a magnetic resonance imaging system, including at least one magnet comprising a high temperature superconductor configured to provide a magnetic field in an imaging volume suitable for acquiring magnetic resonance imaging data. At least one example embodiment of the invention further generally relates to a magnetic resonance imaging system comprising a magnet arrangement with at least one magnet comprising a high temperature superconductor, wherein the at least one magnet confines an imaging volume in at least one spatial direction. At least one example embodiment of the invention further generally relates to a method for manufacturing a magnet arrangement via an additive manufacturing device, comprising the steps: providing a first magnet segment, providing a second magnet segment, aligning the first magnet segment with the second magnet segment and bringing the first magnet segment into contact with the second magnet segment and performing a joining process to bond the first magnet segment to the second magnet segment.

At least one example embodiment of the invention further generally relates to a method for manufacturing a magnet as well as an additive manufacturing device for manufacturing a magnet arrangement.

### BACKGROUND

Magnetic resonance imaging represents an important element of modern imaging diagnostics, as it can deliver high resolution images of a patient anatomy in a relatively short period of time and with limited effects on the human body.

For mapping a body region of the patient, magnetic resonance imaging devices align nuclear spins of the patient with a strong external magnetic field and excite the body region by applying a radio-frequency sequence. Each radio-frequency sequence causes a magnetization of certain nuclear spins in the patient to deviate from the external magnetic field by an amount known as a flip angle. As these excited nuclear spins produce a rotating and decaying magnetization, they can emit (magnetic resonance) signals, which are received via dedicated antennas.

With the aid of magnetic gradient fields, the signals are spatially encoded, making it possible to assign the received signal to a volume element. The received signal is then evaluated, and a three-dimensional imaging representation of the body region is provided. To excite the precession of the spins, magnetic alternating fields with a frequency that corresponds to the Larmor frequency at the respective static magnetic field strength and very high field strengths or powers are to be provided.

The majority of current magnetic resonance imaging systems employs superconductors as magnets for the static magnetic field. These superconductors are operated with high electrical currents and cooled down to temperatures below 10 K. Therefore, current magnetic resonance imaging systems usually comprise a cryostat with liquid helium, which is configured to permanently cool the magnet for the static magnetic field. In contrast, the gradient magnetic field is typically provided by water-cooled resistive gradient coils. The superconductors and the resistive gradient coils usually comprise copper wires, which are wound into coils.

The need for extremely low temperatures in the cryostat and a separate cooling system for the resistive gradient coils increases technical complexity and augments both equipment costs and energy costs associated with the operation of the magnetic resonance imaging system.

### SUMMARY

At least one embodiment of the invention reduces technical complexity and costs associated with the operation of a magnetic resonance imaging system.

Embodiments of the invention are directed to a magnet arrangement, a magnetic resonance imaging system, a method for manufacturing a magnet arrangement, a method for manufacturing a magnet and an additive manufacturing device according to the invention. Further advantageous embodiments are specified in the claims.

At least one embodiment of the inventive magnet arrangement for use in a magnetic resonance imaging system includes at least one magnet, wherein the at least one magnet comprises a high temperature superconductor configured to provide a magnetic field in an imaging volume suitable for acquiring magnetic resonance imaging data and wherein the magnet arrangement confines the imaging volume in at least one spatial direction.

In a further embodiment of the inventive magnet arrangement, the magnet arrangement comprises a second magnet and wherein the at least one magnet and the second magnet are asymmetrically arranged within the magnet arrangement. The second magnet may comprise a high temperature superconductor according to one of the embodiments described above. It is also conceivable, that the second magnet comprises a magnetized pole, a permanent magnet or a superconducting magnet. An asymmetric arrangement of the at least one magnet and the second magnet may signify, that a size, a shape, an amount of magnetic material, a magnetic field strength and/or other properties of the at least one magnet differ from the second magnet. It is also conceivable, that an absolute distance between the at least one magnet and the isocenter is different from an absolute distance between the second magnet and the isocenter.

At least one embodiment of the inventive magnetic resonance imaging system comprises a magnet arrangement with at least one magnet, an imaging volume and a cryostat, wherein the cryostat comprises a cooling fluid thermally coupled with the at least one magnet and configured for cooling the at least one magnet to a predetermined temperature, wherein the at least one magnet confines the imaging volume in at least one spatial direction and wherein the magnetic resonance imaging system is configured to acquire magnetic resonance imaging data from at least a body region of a patient positioned in the imaging volume.

In the inventive method for manufacturing a magnet arrangement for utilization in a magnetic resonance imaging system, at least one magnet of the magnet arrangement is manufactured by applying a high temperature superconductor to a carrier matrix via an additive manufacturing device.

According to an embodiment of the inventive method for manufacturing a magnet for utilization in a magnetic resonance imaging system, the magnet is manufactured in one piece from a high temperature superconductor providing a monolithic high temperature superconductor, wherein a shape of the monolithic high temperature superconductor is configured to confine an imaging volume in at least one spatial direction.

An embodiment of the inventive manufacturing device for manufacturing a magnet arrangement comprises a feeding cylinder and at least one depositing element, wherein the feeding cylinder is rotatably mounted along a rotation axis and wherein the feeding cylinder is configured to feed a substrate to the depositing element via rotation along the rotation axis, wherein the at least one depositing element is movably mounted along at least a first spatial direction and is configured to apply a high temperature superconductor onto a surface of the substrate, wherein the feeding cylinder and/or the at least one depositing element are moveably mounted along at least a second spatial direction in order to apply a plurality of layers of the high temperature superconductor onto the substrate.

At least one embodiment of the invention is directed to magnet arrangement for use in a magnetic resonance imaging system, comprising:
at least one magnet, including a high temperature superconductor configured to provide a magnetic field in an imaging volume suitable for acquiring magnetic resonance imaging data, the magnet arrangement being configured to confine the imaging volume in at least one spatial direction.

At least one embodiment of the invention is directed to a magnetic resonance imaging system, comprising:
the magnet arrangement of an embodiment;
an imaging volume; and
a cryostat, the cryostat includes a cooling fluid thermally coupled with the at least one magnet and configured to cool the at least one magnet to a predetermined temperature,
wherein the at least one magnet is configured to confine the imaging volume in at least one spatial direction and wherein the magnetic resonance imaging system is configured to acquire magnetic resonance imaging data from at least a body region of a patient positioned in the imaging volume.

At least one embodiment of the invention is directed to a method for manufacturing a magnet arrangement for a magnetic resonance imaging system, at least one magnet of the magnet arrangement being manufactured by applying a high temperature superconductor to a carrier matrix via an additive manufacturing device, comprising:
providing a first magnet segment by applying a first layer of the high temperature superconductor to a first element of the carrier matrix via the additive manufacturing device;
providing a second magnet segment by applying a second layer of the high temperature superconductor to a second element of the carrier matrix via the additive manufacturing device;
aligning the first magnet segment with the second magnet segment and bringing the first magnet segment and the second magnet segment into contact in a defined relative position; and
performing a joining process to bond the first magnet segment to the second magnet segment in the defined relative position.

At least one embodiment of the invention is directed to a method for manufacturing a magnet for utilization in a magnetic resonance imaging system, comprising:
manufacturing the magnet in one piece from a high temperature superconductor, a monolithic high temperature superconductor being provided, a shape of the monolithic high temperature superconductor being configured to confine an imaging volume in at least one spatial direction.

At least one embodiment of the invention is directed to an additive manufacturing device for manufacturing a magnet arrangement, the additive manufacturing device comprising:
a feeding cylinder; and
at least one depositing element, the feeding cylinder being rotatably mounted along a rotation axis and the feeding cylinder being configured to feed a substrate to the at least one depositing element via rotation along the rotation axis, the at least one depositing element being movably mountable along at least a first spatial direction and being configured to apply a high temperature superconductor onto a surface of the substrate, at least one of the feeding cylinder and the at least one depositing element being moveably mountable along at least a second spatial direction in order to apply a plurality of layers of the high temperature superconductor onto the substrate

### BRIEF DESCRIPTION OF THE DRAWINGS

Further advantages and details of the present invention may be recognized from the embodiments described below as well as the drawings. The figures show:

FIG. 1 an embodiment of an inventive magnet arrangement,

FIG. 2 an embodiment of an inventive magnet arrangement,

FIG. 3 an embodiment of an inventive magnet arrangement,

FIG. 4 an intermediate product of an inventive method,

FIG. 5 an embodiment of an inventive magnet arrangement,

FIG. 6 an embodiment of an inventive magnet arrangement,

FIG. 7 an intermediate product of an inventive method,

FIG. 8 an embodiment of an inventive additive manufacturing device,

FIG. 9 a flowchart of an inventive method for manufacturing a magnet arrangement,

FIG. 10 a flowchart of an inventive method for manufacturing a magnet,

FIG. 11 an embodiment of an inventive magnetic resonance imaging system.

### DETAILED DESCRIPTION OF THE EXAMPLE EMBODIMENTS

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Various example embodiments will now be described more fully with reference to the accompanying drawings in which only some example embodiments are shown. Specific structural and functional details disclosed herein are merely representative for purposes of describing example embodiments. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Accordingly, known processes, elements, and techniques, may not be described with respect to some example embodiments. Unless otherwise noted, like reference characters denote like elements throughout the attached drawings and written description, and thus descriptions will not be repeated. At least one embodiment of the present invention, however, may be embodied in many alternate forms and should not be construed as limited to only the example embodiments set forth herein.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “connected,” “engaged,” “interfaced,” and “coupled.” Unless explicitly described as being “direct,” when a relationship between first and second elements is described in the above disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

When an element is referred to as being “on,” “connected to,” “coupled to,” or “adjacent to,” another element, the element may be directly on, connected to, coupled to, or adjacent to, the other element, or one or more other intervening elements may be present. In contrast, when an element is referred to as being “directly on,” “directly connected to,” “directly coupled to,” or “immediately adjacent to,” another element there are no intervening elements present.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Before discussing example embodiments in more detail, it is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments of the present invention. This invention may, however, be embodied in many alternate forms and should not be construed as limited to only the embodiments set forth herein.

Units and/or devices according to one or more example embodiments may be implemented using hardware, software, and/or a combination thereof. For example, hardware devices may be implemented using processing circuity such as, but not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one embodiment of the invention relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

At least one embodiment of the inventive magnet arrangement for use in a magnetic resonance imaging system includes at least one magnet, wherein the at least one magnet comprises a high temperature superconductor configured to provide a magnetic field in an imaging volume suitable for acquiring magnetic resonance imaging data and wherein the magnet arrangement confines the imaging volume in at least one spatial direction.

A magnet arrangement may comprise one or more magnets. An imaging volume may be a dedicated space wherein an examination object is placed in order to acquire magnetic resonance image data of the examination object. An examination object may for instance be a patient or any desired body region of a patient. The imaging volume may comprise an isocenter of the magnetic resonance imaging device, the isocenter being characterized by a particularly homogenous magnetic field. The magnet arrangement is configured to confine the imaging volume in at least one spatial direction. However, the magnet arrangement may also confine the imaging volume in a plurality of spatial directions. For example, the imaging volume may be confined by one or more surfaces of the magnet arrangement, wherein a surface of the magnet arrangement may comprise a shape of a plane, a curved plane, an ovoid, a polyhedron and the like.

The at least one magnet of the magnet arrangement of at least one embodiment comprises a high temperature superconductor. It is conceivable, that the at least one magnet consists of a high temperature superconductor. It is also conceivable, that the at least one magnet comprises a predominant share, e.g. 80%, 90% or more, of a material with high temperature superconducting properties. Conceivable examples of high temperature superconductors or materials with high temperature superconducting properties are barium copper oxides (e.g. YBCO, ReBCO), calcium copper oxides (e.g. BSCCO) as well as doped fullerides (e.g. Cs2RbC60), magnesium diboride and the like.

The high temperature superconductor of at least one embodiment is configured to generate a magnetic field in the imaging volume. A magnetic field may be a homogenous magnetic field or a gradient magnetic field permeating the imaging volume and/or the isocenter of the magnet arrangement. The magnetic field may further be temporally invariant or temporally variable.

In providing a magnet arrangement with at least one magnet comprising a high temperature superconductor, the temperature needed for cooling of the at least one magnet can be advantageously increased in comparison to a conventional superconducting magnet arrangement. In increasing the temperature for cooling, an efficiency of a cooling system configured to cool the at least one magnet can be enhanced and energy costs can be favorably reduced.

In one embodiment, the inventive magnet arrangement further includes a carrier matrix, which comprises an electrically insulating material, wherein the high temperature superconductor of the at least one magnet is configured as a pathway or a series of pathways, which are bonded to the carrier matrix.

The carrier matrix may be any kind of element providing a structural support to the at least one magnet. A shape and/or an arrangement of the carrier matrix may be matched with a dimension of the imaging volume and/or a dimension of the at least one magnet. In a preferred embodiment, the carrier matrix at least partially encloses the imaging volume.

The carrier matrix may comprise different materials and/or material compositions. It is conceivable, that the carrier matrix consists of glass, a ceramic material and/or a metal alloy (e. g. a stainless-steel alloy). However, other materials and/or material compositions are also possible. The material and/or material composition of the carrier matrix preferably comprises electrically insulating properties to avoid a conduction or transportation of electric currents through the carrier matrix.

The at least one magnet is configured as a pathway or a series of pathways, which are bonded to the carrier matrix. A pathway may represent a conductor path or a conductor track with arbitrary dimensions. The pathway may be positioned on a surface of the carrier matrix and/or be embedded into the carrier matrix. It is also conceivable, that the pathway permeates the carrier matrix in a complex, three-dimensional manner. The pathway may also comprise a plurality of windings shaped in such way, that an overall shape of the at least one magnet corresponds to a solenoid, a toroid, a cone, a frustum or any other desired shape. A series of pathways may comprise interconnected pathways and/or unconnected pathways. In a preferred embodiment, the pathway or series of pathways is bonded to the carrier matrix via a material bond. For example, the pathway may be applied to the carrier matrix via an additive manufacturing process materially bonding the high temperature superconductor to the carrier matrix.

By providing a carrier matrix, the structural support of the high temperature superconductor can be advantageously improved, particularly when a complex, three-dimensional shape and/or arrangement of the pathway or the series of pathways is employed.

In one embodiment of the inventive magnet arrangement, the at least one magnet comprises a plurality of disjoint sections, which are separated by sections of the carrier matrix.

Disjoint sections may represent electrically and/or mechanically separated parts or pathways of the at least one magnet. It is also conceivable, that the disjoint sections are electrically and/or materially connected, but spatially separated, such as in a solenoidal coil, wherein individual windings are spatially separated along an axial direction of the solenoid. However, the shape and/or arrangement of the at least one magnet is not limited to a solenoid. It is also conceivable, that a pathway of the high temperature superconductor comprises three-dimensional loops or windings with arbitrary shapes, wherein segments, individual loops or windings are separated by the carrier matrix. The spatial separation of the loops or windings may prevent an electrical conduction in any direction deviating from the direction of the pathway of the high temperature superconductor.

A separation of individual pathways of the high temperature superconductor via the carrier matrix may advantageously prevent electrical conduction in undesirable directions along the magnet arrangement.

In a further embodiment of the inventive magnet arrangement, the carrier matrix comprises at least one fluid channel, which is configured to transport a cooling fluid and enable an exchange of heat energy between the cooling fluid and the at least one magnet.

A fluid channel may comprise a hole, a tunnel, a cavity or the like. It is also conceivable, that the fluid channel comprises a plurality of branches, holes, tunnels, cavities or the like, which may be interconnected. Preferably, the fluid channel comprises a three-dimensional network of branches, holes, tunnels or cavities, embedded or incorporated into the carrier matrix. In one embodiment, the fluid channel or branches of the fluid channel are positioned in proximity to pathways of the high temperature superconductor. It is conceivable, that branches of the fluid channel are routed in parallel to pathways of the high temperature superconductor.

The fluid channel is further configured to transport a cooling fluid and enable an exchange of heat energy between the cooling fluid and the high temperature superconductor of the at least one magnet. A cooling fluid may be a gaseous or a liquid medium, that may be transported through the fluid channel using a suitable pump or compressor. The fluid channel may further comprise an inlet and an outlet connected to a pump or a compressor in such a way, that the cooling fluid may be transported through the fluid channel of the carrier matrix in a continuous fashion.

In a preferred embodiment, a material and/or material composition of the carrier matrix comprises a high thermal conductivity, for example a thermal conductivity in the range of 10 to 50 W/mK, 40 to 80 W/mK, 60 to 120 W/mK, or even higher. It is also conceivable that a thickness of the carrier matrix separating the fluid channel from the pathway of the high temperature superconductor is low, e.g. in the range of a few hundred micrometers, a few millimeters or a few centimeters.

By incorporating a fluid channel into the carrier matrix, the cooling fluid can advantageously be separated from the high temperature superconductor to avoid physical or chemical interaction between the high temperature superconductor and the cooling fluid. Furthermore, by incorporating the fluid channel into the carrier matrix, a manufacturing process of the high temperature superconductor may be favorably facilitated.

In a further embodiment, the inventive magnet arrangement comprises a layer structure including a plurality of layers of the high temperature superconductor and a plurality of layers of the carrier matrix in a predefined sequence and wherein the plurality of layers of the high temperature superconductor is materially bonded to the plurality of layers of the carrier matrix.

A layer may be an essentially plane or flat segment of the high temperature superconductor and/or the carrier matrix. For example, the layer may be shaped as a strap, a tape, a bar, a plate and the like, but can also comprise other forms. A layer structure may be constituted by a number of layers of the high temperature superconductor as well as of the carrier matrix. In a preferred embodiment, a sequence of layers of the high temperature superconductor and layers of the carrier matrix is predetermined. For example, the layers of the high temperature superconductor and the carrier matrix may be alternatingly arranged in such way, that a layer of the high temperature superconductor is enclosed from two sides by one or more layers of the carrier matrix.

However, it is also conceivable, that recurring patterns or sequences of layers of the high temperature superconductor and layers of the carrier matrix are avoided. In this case, the sequence of layers may be predetermined on a level of the overall layer structure. A plurality of layers may represent just one layer or more layers of the respective material.

The layers of the high temperature superconductor are bonded to the layers of the carrier matrix within the layer structure. The layers of the high temperature superconductor and the carrier matrix may comprise a material bond, such as an adhesive bond and/or other chemical bonds or any type of bonding achieved by exerting pressure and/or high temperatures to the layer structure. In a preferred embodiment, the layer structure is provided by an additive manufacturing process.

According to the inventive magnet arrangement of at least one embodiment, any desired shape of the magnet arrangement can be advantageously assembled from layers of the high temperature superconductor and layers of the carrier matrix. Thus, the imaging volume may advantageously be shaped according to spatial requirements and/or imaging requirements regarding a specific body region of a patient.

In one embodiment of the inventive magnet arrangement, the at least one magnet comprises a pre-magnetization and is configured to generate a homogenous and temporally invariant magnetic field in the imaging volume at a predetermined temperature.

A pre-magnetization of the at least one magnet may represent a persistent magnetization of the high temperature superconductor. It is conceivable, that the pre-magnetization arises from persistent electrical currents, creating a persistent magnetic state. Furthermore, a magnetic field strength and/or a magnetic field orientation may be trapped in the at least one magnet in such way, that it essentially behaves like a permanent magnet. In order to trap the magnetic field for longer periods of time, the at least one magnet may be contained in or cooled by a cryostat, which is configured to retain a predetermined temperature at which the at least one magnet remains superconducting. For example, such a predetermined temperature may range between 30 and 90 K. However, it is conceivable that the predetermined temperature is lower or higher, depending particularly on the material or material composition of the high temperature superconductor.

In one embodiment, the pre-magnetized high temperature superconductor exerts a homogenous and temporarily invariant magnetic field in the imaging volume. The at least one magnet may comprise an electrical connection to energize the high temperature superconductor. The at least one magnet may also comprise a pre-magnetized monolithic or bulk high temperature superconductor and/or a pathway or a series of pathways of the high temperature superconductor carried by the carrier matrix and arranged in a three-dimensional fashion.

The magnetic field strength and/or magnetic field orientation of the at least one magnet can be tuned, e.g. by using a pre-magnetizing device (such as a reference magnet) with highly accurate magnetization properties. As the magnetic field of the pre-magnetization device may be trapped reproducibly in a plurality of magnets, an effort of adjusting the magnetic field to provide a high magnetic field homogeneity can be reduced advantageously.

In one embodiment, the inventive magnet arrangement further comprises a metal wire track carried by the carrier matrix and electrically connected to the at least one magnet.

For example, the metal wire may comprise a single metal filament or a plurality of metal filaments, a conducting path, a plurality of conducting paths and the like. The metal wire may consist of an electrical conducting metal, as for example copper, silver, aluminum or gold. It is also conceivable, that the metal wire comprises an electrical conducting metal and/or another material, e.g. a second metal, as a core material, which is coated or galvanized with the electrical conducting metal.

The metal wire may be carried by the carrier matrix in such way, that the metal wire is electrically connected with the at least one magnet. It is conceivable, that the metal wire is embedded or partially embedded in the high temperature superconductor of the at least one magnet. It is also conceivable, that the metal wire is positioned in proximity to a pathway of the high temperature superconductor and comprises an electrical connection to the high temperature superconductor. The metal wire may be configured to provide a quench protection circuit, e.g. comprising discrete components like run-down loads, diodes, heating elements or the like. The metal wire may thus provide an alternate current pathway, to prevent heating of the high temperature superconductor if superconductivity breaks down. The metal wire may further be configured to dissipate an electrical current from the at least one magnet to an environment, e.g. a protective earth.

In providing a metal wire connected to the at least one magnet, electrical currents from the high temperature superconductor can be advantageously transferred to a quench protection circuit and/or a protective earth, when a malfunction of the magnetic resonance imaging device occurs.

In a further embodiment of the inventive magnet arrangement, the magnet arrangement comprises a second magnet and wherein the at least one magnet and the second magnet are asymmetrically arranged within the magnet arrangement. The second magnet may comprise a high temperature superconductor according to one of the embodiments described above. It is also conceivable, that the second magnet comprises a magnetized pole, a permanent magnet or a superconducting magnet. An asymmetric arrangement of the at least one magnet and the second magnet may signify, that a size, a shape, an amount of magnetic material, a magnetic field strength and/or other properties of the at least one magnet differ from the second magnet. It is also conceivable, that an absolute distance between the at least one magnet and the isocenter is different from an absolute distance between the second magnet and the isocenter.

A magnet arrangement comprising an asymmetric arrangement of magnets can be advantageously adjusted to facilitate an access of a patient or a body region of the patient to the imaging volume, e.g. by decreasing the size of the second magnet compared to the at least one magnet.

In one embodiment of the inventive magnet arrangement, the magnet arrangement further confines the imaging volume in at least two spatial directions. It is conceivable, that the magnet arrangement comprises a plurality of magnets, which confine the imaging volume in at least two spatial directions. However, the at least one magnet may also comprise bents, angles and/or curved surfaces in such a way, that the at least one magnet confines the imaging volume in at least two spatial directions. Particularly, the at least one magnet or the plurality of magnets may further be configured to at least partially enclose the imaging volume. For example, the magnet arrangement may comprise a U-shape, a V-shape, a C-shape, a bell-shape, a tube-shape or any other shape confining the imaging volume in at least two spatial directions. In a further embodiment, the magnet arrangement confines the imaging volume in a plurality of spatial directions, for example at least three spatial directions, at least four spatial directions or more.

By providing a magnet arrangement configured to confine the imaging volume in two or more spatial directions, the imaging volume can be partially enclosed by the magnet arrangement. This may advantageously increase a magnetic field homogeneity in the imaging volume and a quality of acquired magnetic resonance imaging data.

In one embodiment of the inventive magnet arrangement, the at least one magnet comprises the shape of a tube. A tube may comprise a hollow cylinder enclosing the imaging along at least two spatial directions. In a preferred embodiment, a cross-sectional area of the at least one magnet comprises a circular shape or an oval shape. However, the cross-sectional area may also comprise a polygonal shape, such as a rectangle, a pentagon, a hexagon, or any other regular or irregular polygon. Preferably, the at least one magnet comprises an opening to provide an access to the imaging volume positioned within the at least one magnet. As described above, the at least one magnet may further comprise a solenoid-shaped pathway of the high temperature superconductor wound in a tube-shape, circumferentially enclosing the imaging volume along at least two spatial directions.

In providing tube-shaped magnet arrangement, the imaging volume may be enclosed circumferentially along a longitudinal direction of the tube. Thus, a particularly high magnetic field homogeneity may advantageously be provided within the imaging volume.

At least one embodiment of the inventive magnetic resonance imaging system comprises a magnet arrangement with at least one magnet, an imaging volume and a cryostat, wherein the cryostat comprises a cooling fluid thermally coupled with the at least one magnet and configured for cooling the at least one magnet to a predetermined temperature, wherein the at least one magnet confines the imaging volume in at least one spatial direction and wherein the magnetic resonance imaging system is configured to acquire magnetic resonance imaging data from at least a body region of a patient positioned in the imaging volume.

The magnet arrangement and the at least one magnet may be implemented as described above. A cryostat may be any kind of container, which is configured to store or preserve a cooling fluid at a superconducting temperature of the high temperature superconductor of the at least one magnet. The cryostat may comprise a thermal insulation configured to reduce input of heat energy from components of the magnetic resonance imaging system and/or an environment of the magnetic resonance imaging system. In a preferred embodiment, the cryostat contains a fluid with a low boiling point like argon, nitrogen, neon, helium (e.g. in a gaseous form) and the like. It is conceivable, that the cryostat further comprises a pulse tube refrigerator, a Gifford-McMahon refrigerator, a Sterling cryocooler, a Joule-Thomson cooler and the like, which is configured to cool the cooling fluid in the cryostat to a predetermined temperature. Preferably, the predetermined temperature is lower than the boiling temperature of the respective cooling fluid.

The magnetic resonance imaging system may comprise a patient access configured to provide an entry to the imaging volume. The patient access may comprise an opening with an arbitrary shape and/or geometry configured to receive a body of the patient and/or a body region of the patient. In one example, the patient access is an essentially circular hole providing access to an imaging volume inside a cylindrical magnet arrangement. In a further example, the patient access may represent an opening on a surface of a prismatic or cuboid shaped magnet arrangement. It is also conceivable, that the magnet arrangement includes two magnets comprising two opposing flat surfaces oriented essentially in parallel, thus providing a passage for the patient. In this case, the patient access may comprise an open space between the two flat surfaces of the magnet arrangement or an open space in front of a flat surface of one magnet. However, depending on the shape of the magnet arrangement, the patient access may comprise other shapes as well.

As described above, the imaging volume is confined by the at least one magnet in at least one spatial direction. Particularly, the imaging volume may be confined by the at least one magnet in at least three spatial directions and/or be at least partially enclosed by the at least one magnet.

The magnetic resonance imaging system is configured to acquire magnetic resonance imaging data from at least a body region of a patient positioned in the imaging volume. In order to do so, the magnetic resonance imaging system may comprise any other component required to perform a magnetic resonance imaging sequence as well as process and output acquired magnetic resonance imaging data.

By providing a magnetic resonance imaging system with a magnet arrangement comprising at least one magnet based on a high temperature superconductor, a predetermined temperature for cooling of the at least one magnet may be increased as compared to conventional magnetic resonance imaging systems based on superconductors and liquid helium as a cooling fluid. This may increase the efficiency of the cryostat and/or the respective cooler. Thus, energy costs associated with the operation of the magnetic resonance imaging system may be reduced advantageously.

In one embodiment of the inventive magnetic resonance imaging system, the at least one magnet is configured to generate a homogenous and temporally invariant magnetic field in the imaging volume.

It is conceivable, that the imaging volume encompasses an isocenter of the magnetic resonance device, wherein the magnetic field is particularly homogenous. The isocenter of the magnetic resonance imaging device may be represented by a sphere, an ovoid, or any other shape. It is conceivable, that a diameter of a sphere with the same volume as the isocenter may range between 2 cm and 10 cm, 10 cm and 20 cm, 20 cm and 30 cm or 30 cm and 50 cm. The isocenter may be positioned anywhere within the imaging volume. In one embodiment, the isocenter is smaller than the imaging volume. However, in some conceivable magnetic resonance imaging systems, a dimension of the isocenter may approximately correspond to a dimension of the imaging volume. The magnetic field of the at least one magnet may be configured in such way, that two arbitrarily chosen points in the isocenter differ in magnetic field strength by less than 1 ppm (part per million), less than 5 ppm, less than 10 ppm, less than 15 ppm or less than 20 ppm.

The at least one magnet is further configured to provide a temporally invariant magnetic field in the imaging volume. It is conceivable that the magnetic field provided by the at least one magnet is constant over a time period of several days, several months or several years. The temporarily invariant magnetic field may be a B0 magnetic field.

By providing the homogenous, static magnetic field of the magnetic resonance imaging system with a high temperature superconducting magnet, cooling requirements can be reduced advantageously. Due to reduced cooling requirements, a dimension of the cryostat and/or the cooler and/or a fluid channel may also be reduced, thus favorably decreasing costs of the magnetic resonance imaging system.

In one embodiment, the inventive magnetic resonance imaging system further comprises an electrical connection, which is connected to the at least one magnet, wherein the at least one magnet is configured to generate a gradient magnetic field in the imaging volume in dependence of a current signal provided by the electrical connection.

The electrical connection may for instance comprise wires, tracks and/or rails configured to transport electrical currents in a range of several Watts to several hundred Watts. It is conceivable, that the electrical connection is configured to feed the current signal through the at least one magnet. The current signal may induce a corresponding magnetic field in the imaging volume. In one embodiment, the current signal is applied for a short time period, e.g. microseconds, a few milliseconds or a few seconds, so that the magnetic field is essentially discontinuous.

The at least one magnet is particularly configured to generate a gradient magnetic field in the imaging volume in dependence of the current signal provided by the electrical connection. Preferably, the at least one magnet generates a gradient magnetic field along a first spatial direction. Depending on the shape of the magnet arrangement and/or the imaging volume, the at least one magnet may extend predominantly along the first spatial direction or may comprise a complex, three-dimensional shape. The gradient magnetic field provided by the at least one magnet may be used to assign magnetic resonance signals of the patient to a specific position in the imaging volume.

By using the at least one magnet to generate a gradient magnetic field, a dissipation of electric energy into heat energy, that is usually associated with resistive gradient coils of conventional magnetic resonance imaging systems, may be avoided or substantially reduced. Thus, cooling requirements as well as an electric energy consumption of the magnetic resonance imaging system may be reduced advantageously.

In one embodiment of the inventive magnetic resonance imaging system, the magnet arrangement further includes a second magnet comprising a high temperature superconductor and an electrical connection, wherein the second magnet is configured to generate a gradient magnetic field in the imaging volume in dependence of a current signal provided by the electrical connection.

A structural design and/or a material or a material composition of the second magnet may correspond to a structural design and/or the material or the material composition of the at least one magnet as described above. It is conceivable, that the second magnet is configured to provide a gradient magnetic field along a second spatial direction different from the first spatial direction and/or orthogonal to the first spatial direction in dependence of a current signal provided by the electrical connection.

The at least one magnet and the second magnet may be arranged in different layers of the carrier matrix. It is also conceivable, that the at least one magnet and the second magnet comprise separate high temperature superconductors arranged in separate pathways or series of separate pathways carried by the carrier matrix. The magnet arrangement may further comprise a third magnet consisting of a high temperature superconductor, which is configured to provide a gradient magnetic field along a third spatial direction different from the first spatial direction and the second spatial direction in dependence of a current signal provided by the electrical connection. In a preferred embodiment, the magnet arrangement comprises a high temperature superconducting magnet providing a static magnetic field and three high temperature superconducting magnets providing gradient magnetic fields along three spatial directions oriented essentially perpendicular to one another.

As the at least one magnet, the second magnet and also the third magnet can be cooled via the cryostat, a water-cooling system for cooling of the resistive gradient coils can be favorably avoided. Thus, space for the water-cooling system may be saved and the imaging volume may be favorably increased.

In the inventive method for manufacturing a magnet arrangement for utilization in a magnetic resonance imaging system, at least one magnet of the magnet arrangement is manufactured by applying a high temperature superconductor to a carrier matrix via an additive manufacturing device.

An additive manufacturing device may comprise any device capable of constructing a three-dimensional object in dependence of a digital model of the object, by adding, stacking or laminating material typically in a layer-by-layer or piece-by-piece approach. Examples for additive manufacturing processes, among others, are stereolithography, selective laser sintering or melting, electron-beam additive manufacturing, fused filament fabrication, multi-or poly-jet modelling, binder jet printing and laminated object manufacturing.

In one step of the inventive method, a first magnet segment is provided by applying a first layer of the high temperature superconductor to a first element of the carrier matrix via the additive manufacturing device.

The first layer of the high temperature superconductor may be applied to the first element of the carrier matrix via any of the additive manufacturing processes presented above. In a preferred embodiment, a first element of the carrier matrix may comprise the shape of a stripe, a tape, a plate, a bar, a panel or a sheet. However, shapes like cuboids, prisms, cylinders and the like are also conceivable. The high temperature superconductor is applied to the first element of the carrier matrix as a layer. The application of the first layer may comprise depositing or assembling individual dots, lines or films of the high temperature superconductor onto a surface of the first element of the carrier matrix. It is conceivable, that an entire surface of the first element of the carrier matrix is coated with the first layer of the high temperature superconductor. It is also conceivable, that just a part or section of the first element of the carrier matrix is covered with the first layer of the high temperature superconductor. The surface of the first element of the carrier matrix may comprise a groove or slot, wherein the first layer of the high temperature superconductor is deposited. The groove or slot may comprise any desired form, cross-sectional shape or course along the surface of the first element of the carrier matrix. It is conceivable, that the groove predetermines a routing of a pathway or series of pathways of the high temperature superconductor along the carrier matrix.

In a further step of the inventive method, a second magnet segment is provided by applying a second layer of the high temperature superconductor to a second element of the carrier matrix via the additive manufacturing device.

The application of the second layer of high temperature superconductor may essentially be executed as described above. In a preferred embodiment, the second element of the carrier matrix is disjoint from the first element of the carrier matrix. The first element of the carrier matrix and the second element of the carrier matrix may therefore represent separate parts of the carrier element, that may also comprise different shapes and/or sizes. It is conceivable, that the application of the first layer of the high temperature superconductor on the first element of the carrier matrix is matched with the application of the second layer of the high temperature superconductor on the second element of the carrier matrix in such way, that the first layer and the second layer form a continuous pathway, when the first magnet segment and the second magnet segment are assembled in a predefined orientation.

In a further step, the first magnet segment is aligned with the second magnet segment and brought into contact with the second magnet segment in a predefined relative position. The first magnet segment and the second magnet may be aligned along a common horizontal plane, a common vertical plane or any other common plane. It is also conceivable, that a surface, a side and/or an edge of the first magnet segment is aligned with a surface, a side and/or an edge of the second magnet segment. Preferably, the first magnet segment and the second magnet segment are aligned in such way, that a continuous surface of magnet segments along a common plane is provided, when bringing into contact the first magnet segment with the second magnet segment in the predefined relative position. However, contacting the first magnet segment and the second magnet segment in the predefined relative position may also comprise positioning the first layer of the high temperature superconductor and the second layer of the high temperature superconductor and/or the first element of the carrier matrix and the second element of the carrier matrix on top of each other. In one embodiment, the first magnet segment and the second magnet segment are stacked congruently on top of each other. Particularly, the first magnet segment and the second magnet segment may be brought into contact in such way, that a continuous surface of high temperature superconductor and/or a continuous surface of the carrier matrix along a common plane may be obtained.

The inventive method may further include bringing a third magnet segment, a fourth magnet segment or a plurality of magnet segments into contact with the first magnet segment and/or a second magnet segment in a similar manner. In a preferred embodiment, an adhesive, a thermally activatable adhesive, a resin or other compounds are applied to an interfacial area between two magnet segments, before bringing in contact the magnet segments.

In a further step, a joining process is performed to bond the first magnet segment to the second magnet segment in the predefined relative position.

A joining process may involve any procedure capable of materially joining the first magnet segment to the second magnet and/or a further magnet segment. It is conceivable, that the magnet segments are materially bonded by applying heat, pressure and/or an adhesive to an interfacial area between the magnet segments. For example, the first magnet segment and the second magnet segment may be exposed to a temperature close to a melting point of the high temperature superconductor and/or the carrier matrix. As described above, the first magnet segment and/or the second magnet segment may also comprise a thermally activatable compound, which is configured to materially bond the first magnet segment to the second magnet segment at a predefined temperature. Such a compound may also be activatable by applying a predetermined pressure and/or a chemical compound, which acts as an adhesive and/or a curing agent. The joining process may also comprise an additive manufacturing process as described above.

By providing a method to assemble a magnet arrangement from individual magnet segments, complex three-dimensional shapes of magnet arrangements may be manufactured in a cost-efficient manner. Such shapes may be used to target specific body regions of a patient, which may be difficult to examine in a conventional magnetic resonance imaging system and/or associated with a higher technical effort.

In one embodiment of the inventive method, a side of the first layer of the high temperature superconductor is aligned with a side of the second layer of the high temperature superconductor when aligning the first magnet segment with the second magnet segment.

The aligning of a side of the first layer of the high temperature superconductor with a side of the second layer of the high temperature superconductor may involve positioning the first layer adjacent to the second layer, forming an essentially continuous surface of high temperature superconductor, when aligning the first magnet segment with the second magnet segment. In one example, the first layer and the second layer may be oriented along a common plane. The first layer may also be brought into contact with the second layer, when the first magnet segment is brought into contact with the second magnet segment in the predefined relative position.

It is also conceivable, that the first layer of the high temperature superconductor and the second layer of the high temperature superconductor are aligned in such way, that the first layer of the high temperature superconductor is positioned above or below the second layer of the high temperature superconductor. In this example, the first layer of the high temperature superconductor and the second layer of the high temperature superconductor may be divided by the first element of the carrier matrix and/or the second element of the carrier matrix.

By aligning a side of the first layer of the high temperature superconductor with a side of the second layer of the high temperature superconductor, a pathway of the high temperature superconductor can be advantageously assembled in any desired shape from a plurality of magnet segments.

In a further embodiment of the inventive method, a side of the first element of the carrier matrix is aligned with a side of the second element of the carrier matrix when aligning the first magnet segment with the second magnet segment. The aligning of a side of the first element of the carrier matrix with a side of the second element of the carrier matrix may be carried out in accordance with the aligning of the magnet segments and/or the aligning of the layers of the high temperature superconductor described above. In a preferred embodiment, the first layer of the high temperature superconductor is aligned with the second layer of the high temperature superconductor and the first element of the carrier matrix is aligned with the second element of the carrier matrix when the first magnet segment is aligned with the second magnet segment.

By aligning a side of the first element of the carrier matrix with a side of the second element of the carrier matrix, the magnet arrangement can be advantageously assembled in any desired shape from a plurality of magnet segments.

In one embodiment of the inventive method, the first magnet segment and the second magnet segment confine an imaging volume in at least one spatial direction, when connected in the predefined relative position to perform the joining process to bond the first magnet segment to the second magnet segment.

In one example, the first magnet segment and the second magnet segment may comprise complementary angled sides. The angled sides may be configured to provide a predetermined angle between the first magnet segment and the second magnet segment, when joining the first magnet segment to the second magnet segment along the angled sides. For example, the angle may depend on a desired dimension and/or a desired shape of the imaging volume. It is conceivable, that less than ten magnet segments, less than 50 magnet segments, or less than 100 magnet segments are joined in order to confine the imaging volume. However, the number of magnet segments may also be smaller or higher.

In a preferred embodiment, the first element of the carrier matrix, the second element of the carrier matrix, as well as elements of the carrier matrix of further magnet segments, may already comprise a predefined shape configured to enclose at least a part of the imaging volume before the joining process is performed. For example, the first element, the second element and further elements of the carrier matrix may be arched, bent, dented or shaped in such way to enclose at least a part of the imaging volume. It is conceivable, that the first layer, the second layer, as well as further layers of the high temperature superconductor are applied to these pre-shaped elements of the carrier matrix in an additive manufacturing process as described above.

Pre-shaped elements of the carrier matrix may be easily assembled to the magnet arrangement. Thus, obtaining a desired shape of the imaging volume and/or a desired position and/or shape of the isocenter within the imaging volume may be favorably facilitated. Furthermore, high temperature superconductors may be sensitive to mechanical impacts. Applying a layer of the high temperature superconductor to a surface of a pre-shaped element of the carrier matrix may therefore favorably reduce a risk of fracturing and/or micro-fracturing the high temperature superconductor when assembling the magnet arrangement as compared to bending or forming the carrier matrix after applying the high temperature superconductor.

In one embodiment of the inventive method, the first magnet segment is molded into a predetermined shape, wherein the predetermined shape is configured to at least partially enclose the imaging volume.

A molding of a magnet segment may comprise forming or shaping the magnet segment into a desired shape. For example, the molding may comprise an application of heat and/or pressure and/or chemicals (e.g. solvents, softening agents), e.g. to increase pliability of the magnet segment. In one embodiment, the first magnet segment may comprise the shape of a tape, wherein one main surface of the tape comprises the carrier matrix and an opposite main surface of the tape comprises the high temperature superconductor. The first magnet segment may be molded into a circular or cylindrical shape in such way, that two ends of the tape are brought into contact with each other, thus providing a ring-shaped magnet segment circumferentially confining the imaging volume. Other shapes, as for example spirals, solenoids, ovals, polygons, lemniscates and the like, are also conceivable. In an example, the first magnet segment is molded into a ring shape and the second magnet segment is molded into a corresponding ring shape with a smaller diameter. The second magnet may subsequently be positioned in a ring-shaped opening of the first magnet segment in order to align the second layer of the high temperature superconductor with the first layer of the high temperature superconductor.

The carrier matrix may be particularly thin and/or pliable, in order to enable and/or facilitate molding of the first magnet segment and/or the second magnet segment. It is conceivable, that a third magnet segment, a fourth magnet segment or a plurality of magnet segments is molded in a similar manner.

By molding a magnet segment to a desired shape, applying the high temperature superconductor to an element of the carrier matrix via the additive manufacturing process may be facilitated, as the high temperature superconductor may be applied to an essentially flat surface of the element of the carrier matrix. Thus, manufacturing costs of the magnet arrangement can be reduced advantageously.

In a further embodiment of the inventive method, a fluid channel is established in the first layer of the high temperature superconductor and/or the second layer of the high temperature superconductor when applying the first layer of the high temperature superconductor to the first element of the carrier matrix and/or applying the second layer of the high temperature superconductor to the second element of the carrier matrix.

Establishing a fluid channel in a layer of the high temperature superconductor may comprise leaving out or omitting a fluid channel, when applying the high temperature superconductor to an element of the carrier matrix via the additive manufacturing device. The fluid cannel may comprise an arbitrary cross-sectional shape. A depth of the fluid channel may be lower or equal to the thickness of the layer of the high temperature superconductor. However, it is also conceivable, that the element of the carrier matrix comprises a groove, which is either omitted, partially covered up or entirely covered up when depositing the high temperature superconductor onto the element of the carrier matrix. A depth of the fluid channel may therefore correspond to a depth of the groove on the element of the carrier matrix or the sum of the depth of the groove and the thickness of the layer of the high temperature superconductor. A protective coating or buffer layer may further be applied to the fluid channel, thus sealing the cooling fluid from the high temperature superconductor in order prevent molecular diffusion or contamination.

In a preferred embodiment, the fluid channel in the first layer is established in such way, that it connects to a fluid channel in the second layer, when the first magnet segment and the second magnet segment are aligned and brought into contact in the predefined relative position. This connection may be configured to enable a transport of cooling fluid from the fluid channel in the first layer to the fluid channel in the second layer, when the first magnet segment is bonded to the second magnet segment via the joining process. It is conceivable, that a third magnet segment, a fourth magnet segment or a plurality of further magnet segments also comprise fluid channels, which may yield an interconnected, three-dimensional network of fluid channels across the magnet arrangement, when the magnet segments are bonded to one another in the joining process.

By establishing the fluid channel via the additive manufacturing device, a machining of the high temperature superconductor, e.g. a drilling or milling of the fluid channels, can be avoided. Thus, a risk of fracturing and/or micro-fracturing associated with machining the high temperature superconductor can be reduced advantageously.

In one embodiment of the inventive method, a connecting layer electrically connecting the first layer of the high temperature superconductor and the second layer of the high temperature superconductor is applied via the additive manufacturing device.

A material or a material composition of the connecting layer may correspond to the first layer of the high temperature superconductor and/or of the second layer of the high temperature superconductor. It is conceivable, that the connecting layer is materially bonded to the first layer and the second layer via the additive manufacturing device. Preferably, the connecting layer is configured to transport electrical currents in an order of magnitude required for generating a static magnetic field or a gradient magnetic field as described above. In one embodiment, the connecting layer may be applied or deposited in a routed channel or hole in the first element of the carrier matrix and/or the second element of the carrier matrix via the additive manufacturing device. However, it is also conceivable, that the connecting layer bridges a gap or an interfacial area between the first layer of the high temperature superconductor and the second layer of the high temperature superconductor. Of course, connecting layers may also be provided between further magnet segments in such way, that a plurality of magnet segments is electrically connected via connecting layers.

By providing a connecting layer between the magnet segments, electrical currents may efficiently be transported across interfacial areas between the magnet segments. Thus, an electrically conducting arrangement of magnet segments can be provided. Manufacturing the magnet arrangement from individual magnet segments electrically connected via connecting layers may favorably reduce a technical effort in comparison to manufacturing a magnet arrangement with a continuous layer of the high temperature superconductor.

In a further embodiment of the inventive method, a metal wire is positioned on the first element of the carrier matrix and electrically connected to the first layer of the high temperature superconductor.

A metal wire may comprise a single metal filament or a plurality of metal filaments. In a preferred embodiment, the metal wire may be a gold wire, a copper wire, an aluminum wire, a silver wire or any of those wires galvanized with gold, silver or other metals with high electrical conductivity. The metal wire is positioned on the first element of the carrier matrix. It is conceivable, that the metal wire is glued, soldered and/or mechanically connected to the first element of the carrier matrix. In a preferred embodiment, the metal layer is positioned on the first element of the carrier matrix whilst applying the first layer of the high temperature superconductor to the first element of the carrier matrix via the additive manufacturing device. Thereby, the metal wire may be embedded into the first layer of the high temperature superconductor and/or materially bonded to the first layer of the high temperature superconductor. It is also conceivable, that the metal wire contacts the first layer of the high temperature superconductor at selective points. However, the metal wire may also be routed in proximity to the first layer of the high temperature superconductor and comprise an electrical connection to the first layer of the high temperature superconductor. The metal wire may also be electrically connected to a plurality of layers of high temperature superconductor of further magnet segments in a similar fashion. In a preferred embodiment, each layer of the high temperature superconductor of the magnet arrangement comprises an electrical connection to a metal wire.

In providing a metal wire electrically connected to the layers of the high temperature superconductor of the magnet segments, an electrical current may be favorably dissipated to a quench protection circuit or an environment, when superconducting conditions cannot be met and electric resistivity increases in the high temperature superconductor. Thus, an overheating of the magnetic resonance imaging system may be prevented.

According to an embodiment of the inventive method for manufacturing a magnet for utilization in a magnetic resonance imaging system, the magnet is manufactured in one piece from a high temperature superconductor providing a monolithic high temperature superconductor, wherein a shape of the monolithic high temperature superconductor is configured to confine an imaging volume in at least one spatial direction.

A monolithic high temperature superconductor may comprise a solid, three-dimensional form. For example, the monolithic high temperature superconductor may be shaped as a cuboid, an ovoid, a cone, a frustum, a prism, a toroid, a cylinder and the like. The monolithic high temperature superconductor is configured to confine the imaging in at least one spatial direction. It is also conceivable, that the monolithic high temperature superconductor comprises an opening, an indentation or a cavity configured to enclose at least a part of the imaging volume and/or confine the imaging volume in at least two spatial directions. However, the monolithic high temperature superconductor may also comprise a continuous monolithic pathway, such as a spiral or a solenoid, arranged in such a way to circumferentially enclose the imaging volume.

In a preferred embodiment, the magnet is manufactured by applying a layer of the high temperature superconductor onto a substrate (e.g. a carrier matrix) via an additive manufacturing device. In this context, the term monolithic means, that the high temperature superconductor comprises a single uninterrupted layer, which is continuously applied onto the substrate. However, the single uninterrupted layer may comprise disjoint sections, as for example individual windings of a solenoid. In a further embodiment, the monolithic high temperature superconductor may be manufactured in a batch process. For example, the monolithic high temperature superconductor may be manufactured from chemical agents or precursors in a pre-shaped reaction vessel. The pre-shaped vessel may determine the shape of the monolithic high temperature superconductor and may be detachable from the monolithic high temperature superconductor in a non-destructive manner. It is also conceivable, that the reaction vessel is provided by the carrier matrix and a detachment from the monolithic high temperature superconductor may be omitted.

In one embodiment, a magnet arrangement of the magnetic resonance imaging system may comprise a single monolithic high temperature superconductor. However, the magnet arrangement may also comprise two, three or more monolithic high temperature superconductors arranged in such way to at least partially enclose the imaging volume.

By manufacturing the magnet as a monolithic high temperature superconductor, a manufacturing time of the magnet may be favorably reduced. Thus, a number of manufactured magnets per period of time may be increased and production costs of the magnetic resonance imaging system may be reduced.

In one embodiment of the inventive method, the monolithic high temperature superconductor is manufactured on a carrier matrix, wherein the carrier matrix confines the imaging volume in at least one direction.

The carrier matrix may comprise a material or material composition as described above. Preferably, the carrier matrix consists of a single piece, which is configured to at least partially enclose the imaging volume and/or confine the imaging volume in at least two spatial directions. It is conceivable, that the carrier matrix provides structural support to the monolithic high temperature superconductor. The carrier matrix may further act as a reaction vessel, wherein the monolithic high temperature superconductor is manufactured.

By manufacturing the monolithic high temperature superconductor on a carrier matrix, the magnet may automatically be formed into a desired shaped during the manufacturing process. Thus, separate steps or operations to shape the magnet accordingly may favorably be avoided.

In a further embodiment of the inventive method, the monolithic high temperature superconductor is pre-magnetizing by immersing the monolithic high temperature superconductor in a magnetic field with a predefined magnetic field strength.

A pre-magnetization may be a persistent magnetization as described above. Pre-magnetizing the monolithic high temperature superconductor may involve positioning or immersing the monolithic high temperature superconductor in a magnetic field of a reference magnet with a significantly higher magnetic field strength. For example, a magnitude of the magnetic field strength of the reference magnet may exceed the desired magnetic field strength of the monolithic high temperature superconductor by factor two, factor three, factor four, factor five or even more. Preferably, the reference magnet provides a static magnetic field with particularly high homogeneity in order to ensure magnetic field properties of the monolithic high temperature superconductor as described above. In one embodiment, the monolithic high temperature superconductor is pre-magnetized whilst being cooled by a cryostat to a predetermined temperature. The cryostat may be permanently connected to the magnet and comprise a cooling fluid thermally coupled to the monolithic high temperature superconductor. It is also conceivable, that the cryostat is configured to continuously cool the monolithic high temperature superconductor for extended periods of time, for example several days, several months or several years.

By pre-magnetizing the monolithic high temperature superconductor, a magnetic field may be trapped or frozen in the monolithic high temperature superconductor. Thus, desired magnetic properties of the monolithic high temperature superconductor may be favorably adjusted in reproducible manner.

An embodiment of the inventive manufacturing device for manufacturing a magnet arrangement comprises a feeding cylinder and at least one depositing element, wherein the feeding cylinder is rotatably mounted along a rotation axis and wherein the feeding cylinder is configured to feed a substrate to the depositing element via rotation along the rotation axis, wherein the at least one depositing element is movably mounted along at least a first spatial direction and is configured to apply a high temperature superconductor onto a surface of the substrate, wherein the feeding cylinder and/or the at least one depositing element are moveably mounted along at least a second spatial direction in order to apply a plurality of layers of the high temperature superconductor onto the substrate.

A feeding cylinder may comprise a tube or pipe shape. It is conceivable, that the feeding cylinder is configured to carry a substrate, an element of the carrier matrix or a carrier matrix. For example, a length and/or a diameter of the feeding cylinder may be adapted to fit the element of the carrier matrix or the carrier matrix in such way, that the high temperature superconductor may be applied onto an entire surface or onto dedicated sections of the substrate, the element of the carrier matrix or the carrier matrix via the depositing element. In one embodiment, the feeding cylinder may be the carrier matrix. The feeding cylinder comprises a rotation axis along which the feeding cylinder is rotatably mounted in order to enable a continuous or discontinuous feed of the substrate to the depositing element. The feeding cylinder may also be movably mounted along at least a second spatial direction (e.g. a vertical direction) in order to accommodate for an increasing thickness of a layer of the high temperature superconductor applied via the depositing element.

The depositing element may be configured to apply a high temperature superconductor to a surface of the substrate via any of the additive manufacturing processes described above. The depositing element is movably mounted along at least a first spatial direction (e.g. a horizontal direction) in order to allow for movement along the rotation axis of the feeding cylinder. The depositing element may also be movably mounted along at least a second spatial direction (e.g. a vertical direction), in order to accommodate for an increasing thickness of a layer of the high temperature superconductor applied via the depositing element.

A substrate may be any kind of base and/or underlay, that provides an appropriately shaped surface and/or a structural support to the high temperature superconductor. In one example, the substrate may be a chemically inert material that may be removed easily from the carrier matrix and/or the high temperature superconductor. In a further example, the substrate may be a layer of the high temperature superconductor and/or a layer of the carrier matrix. In particular, the substrate may represent a layer of the high temperature superconductor and/or a layer of the carrier matrix that has been applied in a previous rotation of the feeding cylinder.

With aid of the inventive additive manufacturing device of at least one embodiment, high temperature superconducting magnets of arbitrary shape may be manufactured. Thus, the magnet as well as the imaging volume may be advantageously adapted to comply with a specific body region or body anatomy of a patient.

According to one embodiment, the inventive additive manufacturing device is configured to alternately apply a layer of the carrier matrix and a layer of the high temperature superconductor onto the substrate carried by the feeding cylinder.

Particularly, the additive manufacturing device is configured to apply both the high temperature superconductor as well as the carrier matrix onto the substrate in a consecutive manner. It is conceivable, that the depositing element of the additive manufacturing device is configured to both process a material and/or a material composition of the high temperature superconductor as well as of the carrier matrix. It is also conceivable, that the additive manufacturing device comprises a first depositing element and a second depositing element, wherein the first depositing element may be configured to apply a layer of the high temperature superconductor onto the substrate and the second depositing element may be configured to apply a layer of the carrier matrix onto the substrate. The first depositing element may utilize a first additive manufacturing process different from the second additive manufacturing process utilized by the second depositing element.

By providing an additive manufacturing device of at least one embodiment, that is configured to apply a layer of the high temperature superconductor as well as a layer of the carrier matrix onto a substrate, the manufacturing of the magnet arrangement may favorably occur in one process machine. Thus, an effort and/or a time requirement for changing the additive manufacturing device in order to apply layers of different materials or material compositions may be favorably avoided.

In a further embodiment, the additive manufacturing device comprises at least a second depositing element configured to apply a layer of the carrier matrix onto the substrate carried by the feeding cylinder.

As described above, the additive manufacturing device may comprise a second depositing element configured to apply a layer of the high temperature superconductor to the carrier matrix. It is conceivable, that the second depositing element precedes the first depositing element in such way, that it applies a layer of the carrier matrix onto a substrate before the first depositing element applies a layer of the high temperature superconductor. In a preferred embodiment, the layer of the high temperature superconductor is applied onto the layer of the carrier matrix and/or in proximity to the layer of the carrier matrix applied via the second depositing element. A spacing between the first depositing element and the second depositing element and/or a rotational speed of the feeding cylinder are adjusted in such way, that the layer of the carrier material has cured to a sufficient degree to support applying of a layer of the high temperature superconductor. Likewise, the first depositing element may precede the second depositing element. In a further example, the first depositing element and the second depositing element may be positioned adjacent to one another, so that parallel layers of the high temperature superconductor and the carrier matrix may be applied onto a surface of the substrate at the same time. Of course, other arrangements of the first depositing element and the second depositing element may be implemented to provide a desired sequence of layers and/or pattern of layers of the high temperature superconductor and the carrier matrix.

By providing an additive manufacturing device with a first depositing element and a second depositing element, a layer of the high temperature superconductor and a layer of the carrier matrix can be applied essentially at the same time. Thus, a change of the additive manufacturing device can be favorably avoided. Furthermore, a time requirement for the manufacturing of the magnet arrangement can be reduced, as an applied volume of the high temperature superconductor and the carrier matrix per period of time can be favorably increased using a first depositing element and a second depositing element.

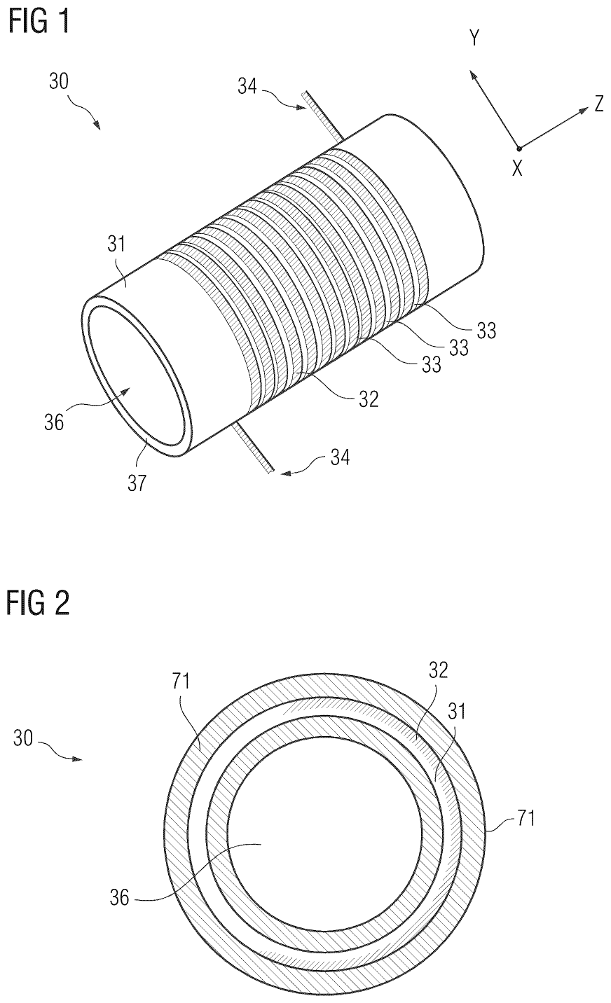

FIG. 1 depicts an embodiment of an inventive magnet arrangement 30, wherein the high temperature superconductor 32 is shaped as a solenoid encompassing a tube-shaped carrier matrix 31. The carrier matrix 31 is configured to enclose an imaging volume 36 in an interior space of the tube. The magnet arrangement 30 comprises a metal wire 33, which is wound around the tube-shaped carrier matrix 31 and electrically connected to the high temperature superconductor 32. It is conceivable, that the metal wire 33 is configured to dissipate an electric current to a quench protection circuit or an environment. The high temperature superconductor 32 may also comprise an electrical connection 34 connected to an external power supply, which is configured to feed an electric current through the high temperature superconductor 32.

In the shown embodiment, the high temperature superconductor 32 comprises a single monolithic pathway embedded in the carrier matrix 31. However, the high temperature superconductor 32 may also comprise a plurality of pathways. The magnet arrangement 30 may further consist of a plurality of magnet segments 40 (e.g. axial or radial slices of the cylindrical magnet arrangement 30), which are assembled to form the cylindrical magnet arrangement 30 and materially bonded to one another. The magnet arrangement 30 is configured to enclose the imaging volume 36 along the Y-direction and the X-direction. A patient 15 may enter the imaging volume 36 along a Z-direction via the patient access 37.

FIG. 2 shows a cross-section of the magnet arrangement 30 depicted in FIG. 1. When mounted in the magnetic resonance imaging system the magnet arrangement 30 may be encapsulated by a cryostat 70. The cryostat 70 contains a cooling fluid 71 thermally coupled to the high temperature superconductor 32 and/or the carrier matrix 31.

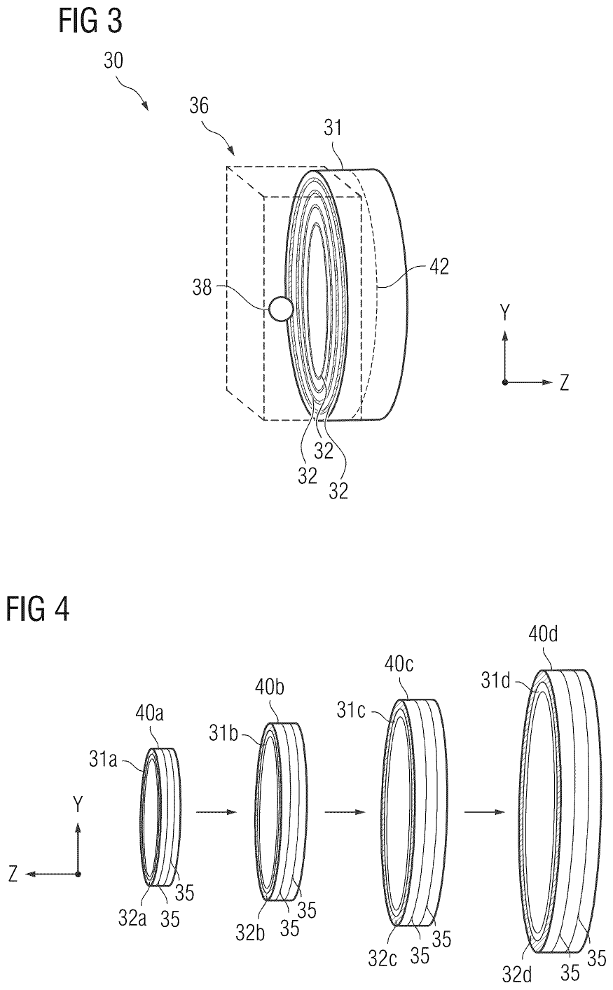

FIG. 3 shows a further embodiment of the inventive magnet arrangement 30. In this example, the magnet arrangement 30 is shaped as a cylinder comprising a plurality of concentrically arranged, ring-shaped high temperature superconductors 32. The magnet arrangement 30 confines the imaging volume 36 in the Z-direction. For illustrative purposes, the imaging volume 36 is depicted as a cuboid-shaped volume positioned in front of the magnet arrangement 30 (dashed lines). The imaging volume 36 contains an isocenter 38, wherein the magnetic field homogeneity is particularly high.

FIG. 4 shows an intermediate product of an embodiment of an inventive method for manufacturing the magnet arrangement 30 depicted in FIG. 3. The intermediate product of the magnet arrangement 30 comprises four magnet segments 40a, 40b, 40c and 40d (40a-d), which have been manufactured by applying layers of the high temperature superconductor 32a, 32b, 32c and 32d (32a-d) onto cylindrical elements of the carrier matrix 31a, 31b, 31c and 31d (31a-31d) via an additive manufacturing device 60 (shown in FIG. 8). In the present example, the layers of the high temperature superconductors 32a-d comprise fluid channels 35, which have been established in the additive manufacturing process as described above. The fluid channels 35 may comprise a meandering shape or any other shape, that provides a large heat transfer surface between the cooling fluid and the layers of the high temperature superconductors 32a-d. The fluid channels 35 may further comprise an inlet and an outlet (not shown) configured to feed the fluid channels 35 with a cooling fluid in a continuous fashion.

In a subsequent step of an embodiment of the inventive method, the magnet segments 40a-40d may be positioned relative to one another by aligning the layers of the high temperature superconductor 32a-32d along the Z-direction. In other words, the magnet segments 40a-40d may be pushed inside of one another, thereby forming a cylindrical magnet arrangement 30 with ring-shaped, concentric layers of the high temperature superconductor 32 as shown in FIG. 3. The fluid channels 35 of the magnet segments 40a-40d may be interconnected by cavities or holes, perforating elements of the carrier matrix 31a-31d and/or the layers of the high temperature superconductor 32 in a radial direction.

It is conceivable, that an adhesive and/or resin is applied onto a radial surface of the magnet segments 40a-40d in order to materially join the magnet segments 40a-40d in the predefined relative position shown in FIG. 3.

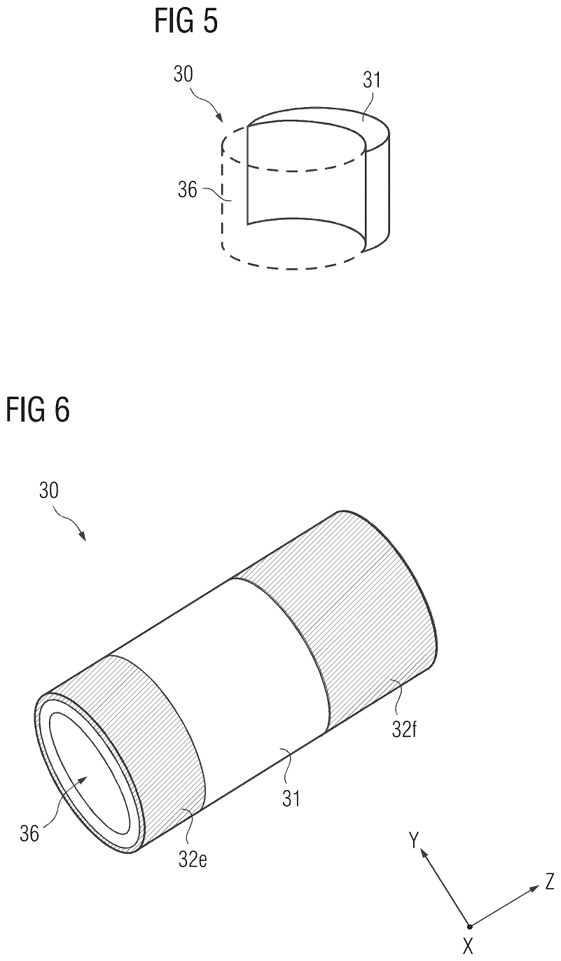

FIG. 5 shows a further embodiment of an inventive magnet arrangement 30. In this embodiment, the high temperature superconductor 32 of the magnet arrangement 30 is embedded within the carrier matrix 31 and may comprise a complex three-dimensional shape. As an example, the magnet may comprise a plurality of concentric, ring-shaped high temperature superconductors 32 (not shown), bent in accordance with the overall shape of the carrier matrix 31. In another example, the magnet may comprise the shape of a lemniscate or a plurality of lemniscates. The carrier matrix 31 partially encloses the imaging volume 36, which is shown for illustrative purposes and not for a quantitative assessment. It is conceivable, that the magnet arrangement 30 shown in FIG. 5 is manufactured in a layer-by-layer approach via an additive manufacturing device 60 (see FIG. 8).

In FIG. 6 a further embodiment of the inventive magnet arrangement 30 is shown. The magnet arrangement 30 comprises two tube-shaped, monolithic high temperature superconductors 32e and 32f. In the present example, the two monolithic high temperature superconductors 32e and 32f are configured to provide a predetermined gradient magnetic field along the Z-direction of the magnet arrangement 30. However, the magnet arrangement 30 may also comprise a magnet for providing a static magnetic field (e.g. as shown in FIG. 1) and/or further magnets, which provide a gradient magnetic field along the Y-direction and/or the X-direction. The further magnets may also comprise high temperature superconductors 32 or superconducting wires.

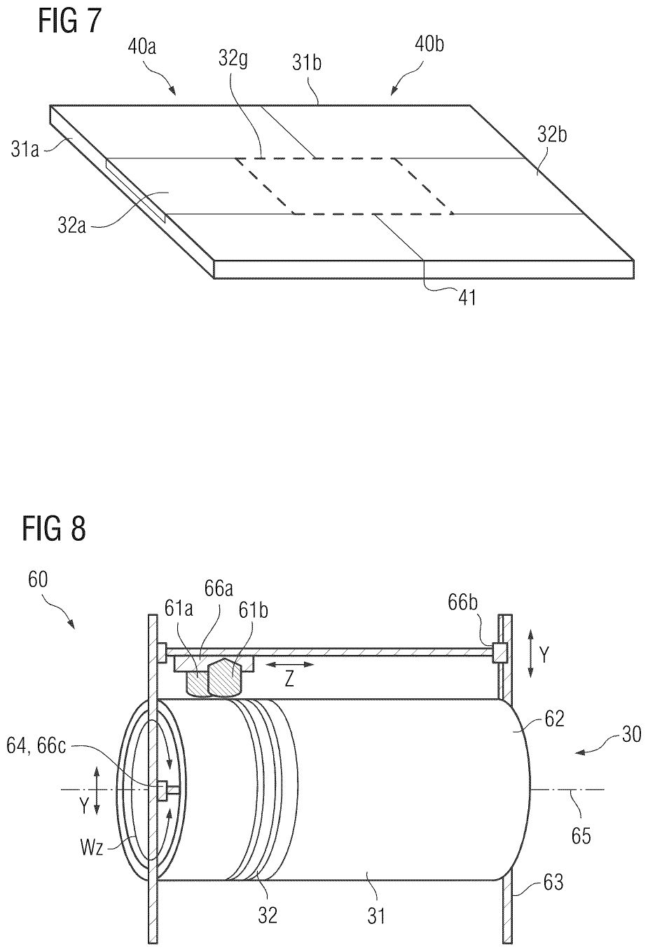

FIG. 7 shows an intermediate product of an embodiment of the inventive method for manufacturing a magnet arrangement 30. The intermediate product comprises two cuboid-shaped magnet segments 40a and 40b connected along an interfacial area 41. The magnet segment 40a is positioned relative to the magnet segment 40b in such way, that a lateral surface of the first layer of the high temperature superconductor 32a is aligned with a lateral surface of the second layer of the high temperature superconductor 32b and a lateral surface of the first element of the carrier matrix 31a is aligned with a lateral surface of the second element of the carrier matrix 31b. The first magnet segment 40a may be materially bonded to the second magnet segment 40b via an adhesive and/or a binding agent. However, an electrical connection between the first layer of the high temperature superconductor 32a and the second layer of the high temperature superconductor 32b is provided by a connecting layer 32g. It is conceivable, that the connecting layer 32g is applied via an additive manufacturing device 60 (see FIG. 8). The layers of the high temperature superconductor 32a and 32b as well as the connecting layer 32g may be embedded in the elements of the carrier matrix 31a and 31b as shown in FIG. 7. However, the layers of the high temperature superconductor 32a and 32b as well as the connecting layer 32g may also protrude from a surface of the elements of the carrier matrix 31a and 31b. They may further comprise cuboid shapes, as shown in FIG. 7, or any other desired shape.

In a subsequent manufacturing step, the first magnet segment 40a and the second magnet segment 40b may be molded into a predetermined shape, as for example a cylindrical shape as shown in FIG. 1, FIG. 4 or in FIG. 6.

FIG. 8 shows an embodiment of an inventive manufacturing device 60. The additive manufacturing device 60 is mounted on a stand 63 comprising a rotatable bearing 64 to enable rotation of the feeding cylinder 62 around the rotation axis 65 (rotation direction Wz). The feeding cylinder 62 may also comprise a guide bearing 66c, for vertically positioning the feeding cylinder 62 along the Y-direction. The stand 63 further comprises a guide bearing 66a to enable positioning of the depositing element 61 along the Z-direction. In the present embodiment, the additive manufacturing device 60 comprises two depositing elements 61a and 61b for applying the carrier matrix 31 as well as the high temperature superconductor 32 via an additive manufacturing process. A position of the two depositing elements 61a and 61b along the Y-direction may be adjusted via a guide bearing 66b. The guide bearings 66a-c, as well as the rotatable bearing 64, may comprise a rail system for vertical positioning along the Y-direction and a motor element (not shown) for automatization of the positioning process. The positioning of the depositing elements 61a and 61b and the feeding cylinder 62 is preferably controlled by a control unit (not shown) configured to transmit appropriate control signals to the motor elements.

The feeding cylinder 62 may comprise a tube-shaped substrate for providing structural support to the magnet arrangement 30. It is conceivable, that the feeding cylinder 62 consists of a material or a material composition of the carrier matrix 31, which may also be provided by another manufacturing process. However, the feeding cylinder may also represent an integral part of the additive manufacturing device 60 (e.g. not a part of the magnet arrangement 30), which feeds sheets or plates of the carrier matrix 31 (e.g. as shown in FIG. 7) or any desired substrate to the depositing element 61.

In the present embodiment, the depositing elements 61a and 61b are spaced apart. The depositing element 61b applies the carrier matrix 31 onto the substrate and/or carrier matrix 31, whereas the depositing element 61a applies the high temperature superconductor 32. In the depicted example, the high temperature superconductor comprises a solenoid-shaped pathway. The depositing elements 61a and 61b are preferably spaced apart in such way, that the material or the material composition of the carrier matrix 31 applied via the depositing element 61a has cured before applying the high temperature superconductor 32.

With an embodiment of the inventive additive manufacturing device 60, all magnet arrangements 30 and or magnet segments 40 shown in the FIGS. 1 to 7 may be manufactured. Of course, other shapes and/or configurations of the magnet arrangement 30 are conceivable.

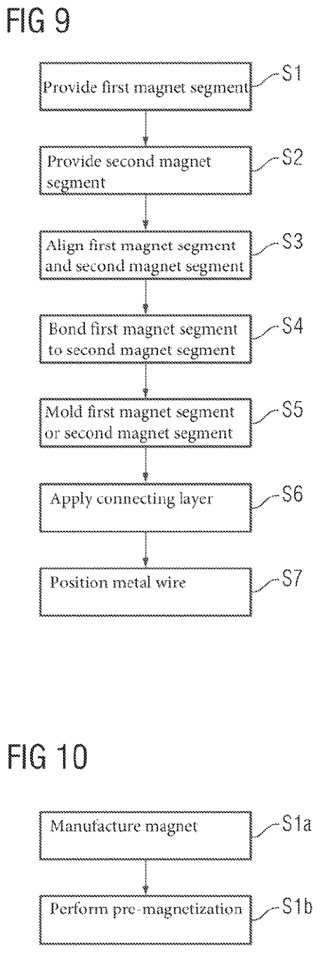

FIG. 9 shows a flow chart of an embodiment of an inventive method for manufacturing a magnet arrangement 30 for utilization in a magnetic resonance imaging system, wherein at least one magnet of the magnet arrangement 30 is manufactured by applying a high temperature superconductor 32 to a carrier matrix 31 via an additive manufacturing device 60.

In a step S1, a first magnet segment 40a is provided by applying a first layer of the high temperature superconductor 32a to a first element of the carrier matrix 31a via the additive manufacturing device 60. In one example, the first element of the carrier matrix 31a may comprise a cylindrical shape as shown in FIG. 4. The first element of the carrier matrix 31a may also represent the feeding cylinder 62, which is pivoted in the additive manufacturing device 60 (see FIG. 8). The first layer of the high temperature superconductor 32a may be applied via the depositing element 61a onto an outer radial surface of the first element of the carrier matrix 31 in such way, that the outer radial surface is partially or fully covered by the first layer of the high temperature superconductor 32a. It is also conceivable, that the radial surface of the first element of the carrier matrix 31a comprises a pre-routed channel, wherein the first layer of the high temperature superconductor 32a is applied in such way, that it is embedded in the first element of the carrier matrix 31a. In one embodiment, a fluid channel 35 is established in the first layer of the high temperature superconductor 32a. The fluid channel 35 may be established by applying the first layer of the high temperature superconductor 32a around the fluid channel 35, thus leaving a passage with a desired route or shape. It is also conceivable, that a fluid channel 35 perforates the first layer of the high temperature superconductor 32a and/or the first element of the carrier matrix 31a along a radial direction of the first magnet segment 40a in order to connect to a fluid channel 35 of another magnet segment 40.

In a step S2, a second magnet segment 40b is provided by applying a second layer of the high temperature superconductor 32b to a second element of the carrier matrix 31b via the additive manufacturing device 60. In the example shown in FIG. 4, the second magnet segment 40b comprises a larger diameter than the magnet segment 40a. Thus, the depositing element 61a may be positioned along the Y-direction via the guide bearing 66b in order to align the depositing element 61a with an outer radial surface of the second element of the carrier matrix 31b. The application of the second layer of the high temperature superconductor 32b may proceed as described above. The magnet arrangement 30 of a magnetic resonance imaging system may comprise further magnet segments 40, which may be manufactured in a similar way. The magnet segments 40 may also comprise other shapes, as for example shown in FIG. 7.

In a step S3, the first magnet segment 40a is aligned with the second magnet segment 40b. It is conceivable, that a side of the first layer of the high temperature superconductor 32a is aligned with a side of the second layer of the high temperature superconductor 32b and/or a side of the first element of the carrier matrix 31a is aligned with a side of the second carrier element of the carrier matrix 31b when the first magnet segment 40a is aligned with the second magnet segment 40b. For example, a side of the first layer of the high temperature superconductor 32a may be a radial surface (as shown in FIG. 4) or a lateral surface (as shown in FIG. 7). Preferably, the magnet segments 40a and 40b are shaped in such way, that a side of the first layer of the high temperature superconductor 32a matches with a side of the second layer of the high temperature superconductor 32b. However, a shape of the first magnet segment 40a can also differ from the shape of the second magnet segment 40b. The relative positioning of the first magnet segment 40a and the second magnet segment 40b may also involve aligning a side of the first element of the carrier matrix 31a with a side of the second element of the carrier matrix 31b, whereby the first layer of the high temperature superconductor 32a remains unaligned with the second layer of the high temperature superconductor 32b. Referring to FIG. 4, this may be the case, if the layers of the high temperature superconductor 31a and 31b are offset with regard to a centerline 42 of the magnet arrangement 30 (see FIG. 3), e.g. to adjust a position and/or a shape of the isocenter 38. The relative positioning of the first magnet segment 40a and the second magnet segment 40b may be performed manually or via a dedicated machine. After aligning the first magnet segment 40a with the second magnet segment 40b, the first magnet segment is brought into contact with the second magnet segment 40b in a predefined relative positioned. The predefined relative position may represent at least a part of the final magnet arrangement (30), as shown for example in FIG. 3.

In a further step S4, a joining process is performed to bond the first magnet segment 40a to the second magnet segment 40b in the predefined position. As described above, a joining process may comprise materially joining the first magnet segment 40a to the second magnet segment 40b. Of course, the joining process may also comprise materially joining a plurality of further magnet segments, as for example a third magnet segment 40c and a fourth magnet segment 40d, to the first magnet segment 40a and the second magnet segment 40b. In a preferred embodiment, the magnet segments 40 are bonded by applying an adhesive or a resin onto an interfacial area 41 between the magnet segments 40. Referring to FIG. 7, this interfacial area 41 may be formed by connecting two lateral surfaces of the two magnet segments 40a and 40b. Referring to FIG. 4, the adhesive or resin may also be applied to radial surfaces of layers of the high temperature superconductor 32a-d and/or inner surfaces of the elements of the carrier matrix 31a-d. Preferably, the adhesive or resin can be activated be applying heat and/or pressure to the magnet segments 40. It is also conceivable, that the magnet segments 40 are materially joined by heating the magnet segments close to a melting temperature of the high temperature superconductor 32 and/or the carrier matrix 31. This may initiate molecular bonds between the magnet segments 40 or provide an interlocking connection, if for example the element of the carrier matrix 31 comprises a profiled surface in contact with the high temperature superconductor 32.

In one embodiment, the magnet segments 40 are radial segments of a tube-shaped magnet arrangement 30. In this example, the magnet segments 40 may comprise arches, which are joined radially in such way, that the provided magnet arrangement 30 confines the imaging volume 36 in at least two spatial directions.

In an optional embodiment S5, the first magnet segment 40a and/or the second magnet segment 40b are molded into a predetermined shape, wherein the predetermined shape is configured to at least partially enclose the imaging volume 36. By molding the magnet segments 40a and 40b, a cylindrical magnet arrangement 30 (as shown in FIG. 1) may be manufactured from cuboid magnet segments 40 (as shown in FIG. 7). For instance, the layers of the high temperature superconductor 32 may be arranged on the elements of the carrier matrix 31 in such way, that a solenoid or a solid cylinder may be obtained (see e.g. FIG. 1 or FIG. 6), when connecting the magnet segments 40 and molding them into the shape of the magnet arrangement 30. However, other shapes may be obtained as well by molding of the magnet segments 40. The molding of the magnet segments 40 may be performed whilst applying heat and/or pressure, in order to increase pliability of the layers of the high temperature superconductor 32 and/or the elements of the carrier matrix 31. It is conceivable, that individual magnet segments 40 are molded into a desired shape and subsequently assembled to the magnet arrangement 30. However, the magnets segments 40 may also be materially joined as described above, before molding the magnet segments 40 into a desired shape. The molding process may be performed manually or by a dedicated machine.

In a further optional step S6, a connecting layer 32g electrically connecting the first layer of the high temperature superconductor 32a and the second layer of the high temperature superconductor 32b is applied via the additive manufacturing device. The connecting layer 32g may comprise a similar material or material composition as the first layer of the high temperature superconductor 32a and the second layer of the high temperature superconductor 32b in order to ensure a high material compatibility and a proper material bonding. Referring to FIG. 7, the connecting layer 32g may bridge an interfacial area between the first magnet segment 40a and the second magnet segment 40b. It is conceivable, that heat is applied to the connecting layer 32g in order bond it to the first layer of the high temperature superconductor 32a and/or the second layer of the high temperature superconductor 32b. The application of heat may induce selective melting of a material or material composition of the connecting layer 32g as well as of the layers of the high temperature superconductor 32a and 32b. It is also conceivable, that a plurality of layers of the high temperature superconductor 32 may be electrically connected via a plurality of connecting layers 32g.

In an optional step S7, a metal wire 33 is positioned on the first element of the carrier matrix 31a and/or the second element of the carrier matrix 31b and electrically connected to the first layer of the high temperature superconductor 32a and/or the second layer of the high temperature superconductor 32b. Referring to FIG. 4, the metal wire 33 may be positioned on an outer radial surface of the first element of the carrier matrix 31a, before or whilst the first layer of the high temperature superconductor 32a is applied via the additive manufacturing device. Thus, the metal wire 33 may be electrically connected to the first layer of the high temperature superconductor 32a. As described above, the first element of the carrier matrix 31a may comprise holes or cavities extending in a radial direction. These holes or cavities may be used to pass through the metal wire 33 from the first element of the carrier matrix 31a to the second element of the carrier matrix 31b, where it may be positioned along an outer radial surface and electrically connected to the second layer of the high temperature superconductor 32b. In doing so, a plurality of layers of the high temperature superconductor 32 may be electrically connected to the metal wire 33. The electrical wire 33 may comprise an electrical connection to a quench protection circuit or an environment, in order to dissipate electric energy from the layers of the high temperature superconductor 32 in the case of a malfunction of the magnetic resonance imaging device.

FIG. 10 depicts a flowchart of an embodiment of an inventive method for manufacturing a magnet for utilization in a magnetic resonance imaging system.

In a step S1a, the magnet is manufactured in one piece from a high temperature superconductor 32, wherein a monolithic high temperature superconductor 32 is provided and wherein a shape of the monolithic high temperature superconductor 32 is configured to confine the imaging volume 36 in at least one spatial direction. As described above, the manufacturing of the monolithic high temperature superconductor 32 may comprise an additive manufacturing process, wherein the monolithic high temperature superconductor 32 is manufactured as an uninterrupted layer, which is continuously applied to a substrate. For example, the uninterrupted layer of the monolithic high temperature superconductor 32 may be shaped like a solenoid (as shown in FIG. 1) or like a solid tube (as shown in FIG. 6). However, other shapes are also conceivable. For example, the monolithic high temperature superconductor 32 may comprise the shape of a solid wedge as shown in FIG. 5. The monolithic high temperature superconductor 32 is preferably enclosed in the carrier matrix 31 as well as a cryostat 70, in order to provide cooling and structural support.

In one embodiment, the monolithic high temperature superconductor is manufactured in a batch process. This may comprise processing chemical agents or precursors at a predefined pressure and/or temperature in a reaction vessel. It is conceivable, that the monolithic high temperature superconductor 32 is removed from the reaction vessel and assembled in a magnet arrangement 30. However, the reaction vessel may also represent a carrier matrix 31 or a part of the magnet arrangement 30.

In a step S1b, the monolithic high temperature superconductor 32 is pre-magnetizing by immersing the monolithic high temperature superconductor 32 in a magnetic field with a predefined magnetic field strength. For pre-magnetization, the monolithic high temperature superconductor 32 may be exposed to a magnetic field of a reference magnet with a predefined magnetic field strength. Particularly, the monolithic high temperature superconductor 32 may be cooled to a predetermined temperature, for example a superconducting temperature of the high temperature superconductor 32, in order to permanently trap or freeze the magnetic field of the reference magnet in the monolithic high temperature superconductor.

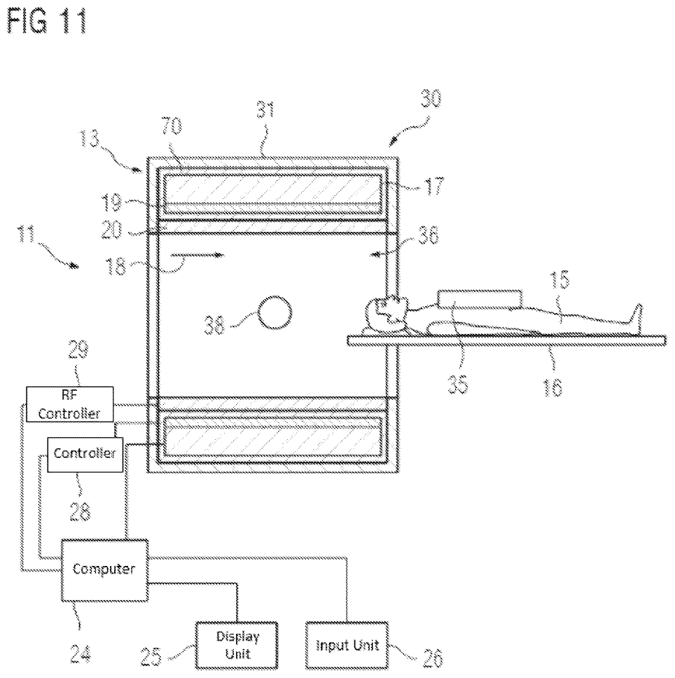

FIG. 11 shows an embodiment of an inventive magnetic resonance imaging system 11. The magnetic resonance imaging system 11 comprises a magnetic resonance device 13 with a static field magnet 17 that produces a constant, static magnetic field 18. The static magnetic field 18 comprises an isocenter 38 and a cylindrical imaging volume 36 for receiving a patient 15. The imaging volume 36 is surrounded circumferentially by the magnet arrangement 30 (as shown in FIG. 1). The patient 15 can be moved by a patient support 16 into the imaging volume 36, in particular into the isocenter 38. The magnetic resonance device 13 is screened from an environment by a housing shell 31.

The magnetic resonance device 13 further comprises a gradient magnet arrangement 19 generating gradient magnetic fields, which are used for spatially encoding the magnetic resonance signals during an imaging procedure. The gradient magnet arrangement 19 is activated by a gradient controller 28 via an appropriate current signal. In one example, the gradient magnet arrangement 19 may comprise a plurality of monolithic high temperature superconductors 32 (see also FIG. 6) to generate gradient magnetic fields in multiple directions. The gradient magnet arrangement 19 as well as the static field magnet 17 may be positioned in a cryostat 70, which is configured to cool the high temperature superconductor 32 to a predetermined temperature.

In the depicted embodiment, the magnetic resonance device 13 further comprises a radio-frequency antenna 20, which is a body coil permanently integrated into the magnetic resonance device 13. The radio-frequency antenna 20 is operated via a radio-frequency controller 29 that controls the radio-frequency antenna 20 so as to radiate radio-frequency sequences into an examination space, which is essentially formed by the imaging volume 36. Each radiated radio-frequency sequence causes the magnetization of certain nuclear spins in the patient 15 to deviate from the static magnetic field 18 by an amount known as a flip angle. As these excited nuclear spins relax and return to the steady state, they emit magnetic resonance signals. The radio-frequency antenna 20 is configured to receive the magnetic resonance signals from the patient 15. The magnetic resonance imaging system 11 further comprises a local coil 21, which is positioned on a region of the body of the patient 15 to be examined for receiving the magnetic resonance signals.

The magnetic resonance imaging system 11 shown can naturally have further components that magnetic resonance imaging systems usually have. The general operation of a magnetic resonance imaging system is known to those skilled in the art, so a more detailed description is not necessary herein. The magnetic resonance imaging system 11 also has a computer 24. The computer 24 controls the magnetic resonance imaging system 11. The computer can be connected to a display unit 25 and an input unit 26. Preparatory information for a preparation of the magnetic resonance imaging can be provided to a user on the display unit 25. Via the input unit 26, information and/or parameters for the preparation of the magnetic resonance imaging can be entered. The display unit 25 and the input unit 26 can also be embodied as a combined touch interface.

It shall be understood that the embodiments described above are to be recognized as examples. Individual embodiments may be extended by features of other embodiments. In particular, a sequence of the steps of the inventive methods are to be understood as example. The individual steps can also be carried out in a different order or overlap partially or completely in time.

The patent claims of the application are formulation proposals without prejudice for obtaining more extensive patent protection. The applicant reserves the right to claim even further combinations of features previously disclosed only in the description and/or drawings.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

None of the elements recited in the claims are intended to be a means-plus-function element within the meaning of 35 U.S.C. § 112(f) unless an element is expressly recited using the phrase “means for” or, in the case of a method claim, using the phrases “operation for” or “step for.”

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1.-15. (canceled)

16. A method for manufacturing a magnet arrangement for a magnetic resonance imaging system, at least one magnet of the magnet arrangement being manufactured by applying a high temperature superconductor to a carrier matrix via an additive manufacturing device, comprising:
providing a first magnet segment by applying a first layer of the high temperature superconductor to a first element of the carrier matrix via the additive manufacturing device;
providing a second magnet segment by applying a second layer of the high temperature superconductor to a second element of the carrier matrix via the additive manufacturing device;
aligning the first magnet segment with the second magnet segment and bringing the first magnet segment and the second magnet segment into contact in a defined relative position; and
performing a joining process to bond the first magnet segment to the second magnet segment in the defined relative position.

17. The method of claim 16, wherein a side of the first layer of the high temperature superconductor is aligned with a side of the second layer of the high temperature superconductor during the aligning of the first magnet segment with the second magnet segment.

18. The method of claim 16, wherein a side of the first element of the carrier matrix is aligned with a side of the second element of the carrier matrix during the aligning of the first magnet segment with the second magnet segment.

19. The method of claim 16, wherein the first magnet segment and the second magnet segment confine an imaging volume in at least one spatial direction, when connected in the defined relative position to perform the joining process to bond the first magnet segment to the second magnet segment.

20. The method of claim 16, further comprising:
molding the first magnet segment into a shape, the shape being configured to at least partially enclose an imaging volume.

21. The method of claim 16, wherein a fluid channel is established in at least one of the first layer of the high temperature superconductor and the second layer of the high temperature superconductor during at least one of the applying of the first layer of the high temperature superconductor to the first element of the carrier matrix and the applying of the second layer of the high temperature superconductor to the second element of the carrier matrix.

22. The method of claim 16, further comprising:
applying a connecting layer electrically connecting the first layer of the high temperature superconductor and the second layer of the high temperature superconductor, via the additive manufacturing device.

23. The method of claim 16, further comprising:
positioning a metal wire on the first element of the carrier matrix and
electrically connecting the metal wire to the first layer of the high temperature superconductor.

24. A method for manufacturing a magnet for utilization in a magnetic resonance imaging system, comprising:
manufacturing the magnet in one piece from a high temperature superconductor, a monolithic high temperature superconductor being provided, a shape of the monolithic high temperature superconductor being configured to confine an imaging volume in at least one spatial direction.

25. The method of claim 24, wherein the monolithic high temperature superconductor is manufactured during the manufacturing, on a carrier matrix, the carrier matrix confining the imaging volume in at least one direction.

26. The method of claim 24, further comprising:
pre-magnetizing the monolithic high temperature superconductor by immersing the monolithic high temperature superconductor in a magnetic field with a defined magnetic field strength.

27. An additive manufacturing device for manufacturing a magnet arrangement, the additive manufacturing device comprising:
a feeding cylinder; and
at least one depositing element, the feeding cylinder being rotatably mounted along a rotation axis and the feeding cylinder being configured to feed a substrate to the at least one depositing element via rotation along the rotation axis, the at least one depositing element being movably mountable along at least a first spatial direction and being configured to apply a high temperature superconductor onto a surface of the substrate, at least one of the feeding cylinder and the at least one depositing element being moveably mountable along at least a second spatial direction in order to apply a plurality of layers of the high temperature superconductor onto the substrate.

28. The additive manufacturing device of claim 27, wherein the additive manufacturing device is configured to alternately apply a layer of a carrier matrix and a layer of the high temperature superconductor onto the substrate carried by the feeding cylinder.

29.-36. (canceled)

37. The method of claim 17, wherein a side of the first element of the carrier matrix is aligned with a side of the second element of the carrier matrix during the aligning of the first magnet segment with the second magnet segment.

38. The method of claim 17, further comprising:
molding the first magnet segment into a shape, the shape being configured to at least partially enclose an imaging volume.

39. The method of claim 17, further comprising:
applying a connecting layer electrically connecting the first layer of the high temperature superconductor and the second layer of the high temperature superconductor, via the additive manufacturing device.

40. The method of claim 17, further comprising:
positioning a metal wire on the first element of the carrier matrix and electrically connecting the metal wire to the first layer of the high temperature superconductor.

41. The method of claim 25, further comprising:
pre-magnetizing the monolithic high temperature superconductor by immersing the monolithic high temperature superconductor in a magnetic field with a defined magnetic field strength.

42. The additive manufacturing device of claim 27, wherein the additive manufacturing device is further configured to:
provide a first magnet segment by applying a first layer of the high temperature superconductor to a first element of a carrier matrix;
provide a second magnet segment by applying a second layer of the high temperature superconductor to a second element of the carrier matrix via the additive manufacturing device;
align the first magnet segment with the second magnet segment and bringing the first magnet segment and the second magnet segment into contact in a defined relative position; and
perform a joining process to bond the first magnet segment to the second magnet segment in the defined relative position.
